(19) United States
(12) Patent Application Publication
(10) Pub. No.: US 2004/0121086 A1
(43) Pub. Date: Jun. 24, 2004

(54) Thin film depositing method and apparatus

(76) Inventors: Tomoko Takagi, Yokohama-shi (JP); Masashi Ueda, Yokohama-shi (JP); Norikazu Ito, Yokohama-shi (JP)

Correspondence Address: OSTROLENK FABER GERB & SOFFEN, 1180 AVENUE OF THE AMERICAS, NEW YORK, NY, 100368403

(21) Appl. No.: 10/726,300

(22) Filed: Dec. 1, 2003

(30) Foreign Application Priority Data
May 31, 2002 (JP) 2002-160676

(51) Int. Cl. C23C 16/00

(52) U.S. Cl. 427/573; 118/723 E; 118/723 MP; 118/719; 427/569

(57) ABSTRACT

A thin film depositing method comprising placing a substrate in a heating chamber; allowing a first gas to flow inside the heating chamber to heat the substrate through heat exchange with the first gas; moving the substrate to a deposition chamber, evacuating the deposition chamber, and then supplying a second gas into the deposition chamber; and causing an electrical discharge in the second gas such that the second gas decomposes into decomposition components and the decomposition components adhere to a substrate surface to deposit a film thereon, wherein the first gas is a gas from which moisture and organic substances have been removed. The time required for depositing thin films is reduced thereby improving the throughput, increases in apparatus costs are suppressed, and a thin film having good properties is obtained. A thin film depositing apparatus is also provided.

### BACKGROUND OF THE INVENTION

1.Field of the Invention

This invention relates to a thin film depositing method and apparatus, and more particularly, to a thin film depositing method and apparatus which deposits a thin film on a substrate after heating the substrate with a gas free of impurities such as moisture, organic substances and the like which, when adsorbed on a substrate, would impair the properties of the thin film deposited thereon.

2. Description of the Related Art

In general, as a method for depositing various thin films such as amorphous silicon which is used in solar cells and thin-film transistors, there is known a plasma enhanced chemical vapor deposition method (PCVD method). The PCVD method includes introducing material gases for depositing a film into a chamber where a substrate is placed under vacuum, and introducing high-frequency electric power into the chamber to cause an electrical discharge in the gas such that the gas decomposes to form decomposition components which adhere to a surface of the substrate to deposit a film on the surface of the substrate. In many cases, the substrate of a solar cell is in advance formed with a transparent electroconductive film (for example, tin dioxide (SnO₂), zinc oxide (ZnO) or the like in the case of an amorphous silicon thin-film solar cell), and a thin film is deposited on this electrode surface. In addition, in depositing thin films, substrates are heated in advance to a predetermined temperature, and for the purpose of ensuring a uniform film thickness and quality, the uniformity of the temperature of the substrates becomes important.

Conventionally, as a method of depositing thin films for solar cells using a PCVD method, there has been proposed a method which includes placing a substrate in a load lock chamber, evacuating the interior of the load lock chamber to a predetermined pressure, heating the substrate under vacuum with a radiation heating lamp, moving the heated substrate to a deposition chamber, and depositing a thin film in the deposition chamber by the PCVD method.

In addition, as described in Japanese Patent Application Unexamined Publication No. 2001-187332, a method has been proposed in which a substrate is placed in a heating chamber, a gas at a predetermined temperature exceeding room temperature is subjected to forced convection inside the heating chamber, the substrate is heated through heat exchange with the gas, the heated substrate is placed in a load lock chamber, followed by evacuating the load lock chamber while heating the substrate with a radiation heating lamp, the heated substrate is moved to a deposition chamber, and deposition of a thin film is effected inside the deposition chamber by the PCVD method.

It is to be noted, however, that with the above-mentioned conventional thin film depositing method and apparatus, it takes a very long time to heat the substrate in a vacuum with a radiation heating lamp because of the very high infrared radiation reflectance of the transparent electroconductive film, resulting in the throughput (productivity of making the films) being lowered. In addition, because the radiation heating lamp uses electrical energy the cost of which per unit of energy is high as the heat source, the running cost for heating the substrate is high as compared with the case where other energy sources are employed. Furthermore, the necessity of lengthening the lamp itself and increasing the number of lamps in accordance with upsizing of substrates has caused an increase in the initial cost.

With the method proposed in Japanese Patent Application Unexamined Publication No. 2001-187332 in which the substrate is heated through heat exchange with a gas, impurities, i.e., moisture, organic substances and the like contained in the gas, are adsorbed on a substrate surface upon contact therewith so as to degrade the properties of the thin film which is deposited on the substrate. Although these adsorbates can subsequently be removed from the substrate by evacuating the load lock chamber to a vacuum, it takes time, resulting in the throughput being lowered. In addition, there was a problem that, because it is necessary to provide a heat-retaining mechanism for suppressing a reduction in the temperature of the substrate while removing the adsorbates through evacuation, an additional cost was incurred for the mechanism.

### SUMMARY OF THE INVENTION

This invention has been made in view of such circumstances, and an object thereof is to provide a thin film depositing method and apparatus which make it possible to shorten the time required for depositing thin films and improve the throughput as well as to reduce the depositing costs.

In order to attain the object, according to an aspect of this invention, there is provided a thin film depositing method comprising the steps of: placing a substrate in a chamber; causing a gas to flow inside the chamber to heat the substrate through heat exchange with the gas; evacuating the chamber; and depositing a film on a surface of the substrate heated in the chamber.

With the above thin film depositing method, heating of the substrate, evacuation, and deposition of a film on the substrate surface may be performed in a single chamber. Thus, apparatus costs may be markedly suppressed.

According to another aspect of this invention, there is provided a thin film depositing method comprising the steps of: placing a substrate in a heating chamber; causing a first gas to flow inside the heating chamber to heat the substrate through heat exchange with the first gas; moving the substrate to a deposition chamber, evacuating the deposition chamber, and then supplying a second gas into the deposition chamber; and causing an electrical discharge in the second gas such that the second gas decomposes into decomposition components which adhere to a surface of the substrate to deposit a film thereon, wherein the first gas is a gas from which moisture and organic substances have been removed.

With the above thin film depositing method, because the gas from which impurities such as moisture and organic substances have been removed is used as the first gas which heats the substrate through heat exchange, almost no impurities which would impair the properties of the thin film deposited thereon are adsorbed on the surface of the substrate during the heating of the substrate, and because the substrate, after being heated, is exposed to an atmosphere only of the second gas which is the film material, it takes little time to evacuate the surroundings of the substrate to remove adsorbates adhering to the surface of the substrate. Thus, the time required for the evacuation prior to the film deposition can be shortened, with the result that the time required for depositing thin films can be shortened. Furthermore, because almost no impurities such as moisture and organic substances which would degrade the properties of the thin films are adsorbed on the substrate, the properties of the thin film which is deposited on the substrate will not be degraded.

Preferably, in the above thin film depositing method, the first gas is an inert gas.

With this thin film depositing method, because an inert gas from which impurities such as moisture and organic substances have been removed is used as the first gas, the substrate (the substrate and the thin film formed on the substrate) does not undergo oxidation if the substrate is not an oxide, and in addition because no oxygen is adsorbed on the substrate surface, properties of the thin film which is deposited on the substrate will not be degraded.

Preferably, the first gas is nitrogen gas.

With this thin film depositing method, because nitrogen gas from which impurities such as moisture and organic substances have been removed is used as the first gas, the adsorption to the substrate surface during heating of impurities which would impair properties of a thin film is suppressed. Because nitrogen gas is relatively inexpensive, substrates may be heated relatively inexpensively.

According to still another aspect of this invention, there is provided a thin film depositing apparatus comprising: a chamber; a substrate placed in the chamber; a gas which flows inside the chamber to heat the substrate through heat exchange with the gas; and a pumping system which evacuates the chamber, whereby a film is deposited on a surface of the substrate in the chamber.

With the above thin film depositing apparatus, heating of the substrate, evacuation, and deposition of a film on the substrate surface may be performed in a single chamber. Thus, apparatus costs can be markedly suppressed.

According to yet another aspect of this invention, there is provided a thin film depositing apparatus comprising: a heating chamber; a substrate placed in the heating chamber; a gas which flows inside the heating chamber to heat the substrate through heat exchange with the gas; and a deposition chamber in which a film is deposited on a surface of the substrate, the deposition chamber being located downstream of and connected to the heating chamber through a valve, wherein the gas is a gas from which moisture and organic substances have been removed.

With the above thin film depositing apparatus, because the gas from which impurities such as moisture and organic substances have been removed is used as the gas which heats the substrate through heat exchange, almost no impurities which would impair properties of the thin film deposited thereon are adsorbed to the substrate surface during heating of the substrate, and because the substrate, after being heated, is exposed to an atmosphere only of a gas which forms the film material, it takes little time to evacuate the surroundings of the substrate to remove the adsorbates adhering to the substrate surface. Thus, the time required for the evacuation prior to the film deposition can be shortened, with the result that the time required for depositing thin films can be shortened. Because it takes little time to remove adsorbates, it is not necessary to provide a load lock chamber with a radiation heating lamp for retaining the heat of the substrate during the evacuation of around the substrate, thereby dispensing with the cost therefor. Furthermore, because almost no impurities such as moisture and organic substances which would deteriorate properties of a thin film are adsorbed on the substrate, properties of the thin film deposited on the substrate will not be deteriorated.

Preferably, in the above thin film depositing apparatus, the gas is an inert gas.

With this thin film depositing apparatus, because an inert gas from which impurities such as moisture and organic substances have been removed is used as the gas, the substrate (the substrate and the thin film formed on the substrate) does not undergo oxidation if the substrate is not an oxide, and in addition because no oxygen is adsorbed on the substrate surface, properties of the thin film which is deposited on the substrate will not be degraded.

Preferably, the gas is nitrogen gas.

With this thin film depositing apparatus, because nitrogen gas from which impurities such as moisture and organic substances have been removed is used as the gas, impurities which would impair properties of a thin film are suppressed from being adsorbed on the substrate surface during heating. Because nitrogen gas is relatively inexpensive, substrates may be heated relatively inexpensively.

Preferably, the thin film depositing apparatus of this invention further comprises a compression cooler which removes moisture and organic substances from the gas.

Preferably, the thin film depositing apparatus of this invention further comprises a filter device which removes moisture and organic substances from the gas.

The above and other objects and features of the present invention will become more apparent from the following description taken in conjunction with the accompanying drawings.

### BRIEF DESCRIPTION OF THE DRAWINGS

FIG. 1 is a front sectional view of a thin film depositing apparatus according to an embodiment of this invention.

FIG. 2 is a schematic side view of a substrate holder of the thin film depositing apparatus according to an embodiment of this invention.

FIG. 3A is a schematic side view of a heating chamber of the thin film depositing apparatus which is used in an embodiment of this invention.

FIG. 3B is a schematic view of one example of a compression cooler apparatus usable in this invention.

FIG. 3C is a schematic view of one example of a filter apparatus usable in this invention.

FIG. 4 is a schematic side view of a p-type-layer-, i-type-layer-, and n-type-layer-deposition chamber of the thin film depositing apparatus according to an embodiment of this invention.

### DETAILED DESCRIPTION OF THE PREFERRED EMBODIMENTS

Embodiments of this invention will now be described with reference to the attached drawings.

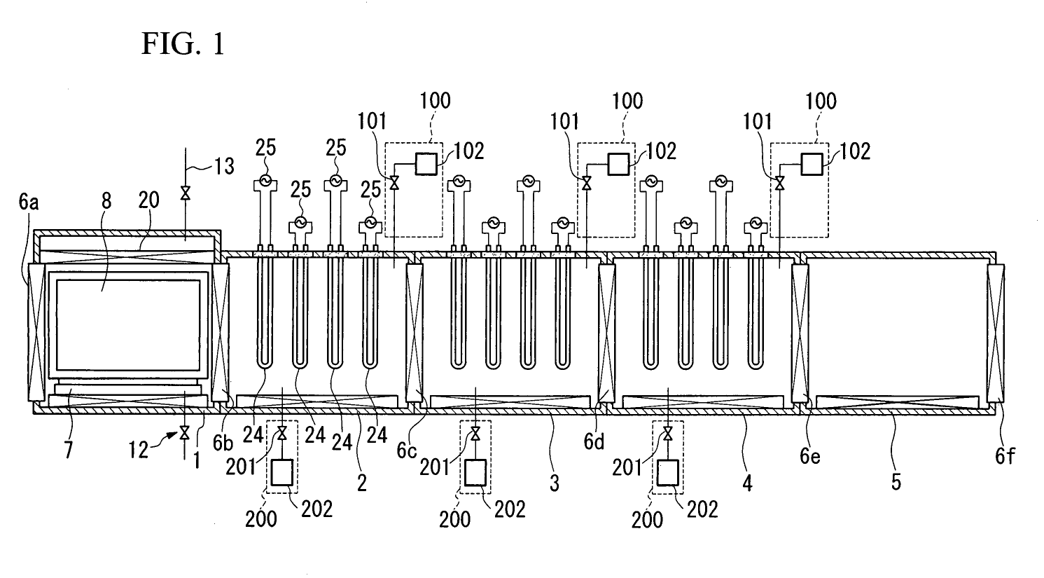

In FIG. 1, a thin film depositing apparatus comprises a heating chamber 1 for heating substrates 8, a p-type layer deposition chamber 2 for depositing a p-type semiconductor thin film (p-type layer) on each substrate 8, an i-type layer deposition chamber 3 for depositing an intrinsic semiconductor thin film (i-type layer) on the substrates 8, an n-type layer deposition chamber 4 for depositing n-type semiconductor thin film (n-type layer) on the substrates 8, and an unload lock chamber 5 for taking out the substrates 8, which are articulated by gate valves 6b-6e, respectively.

Each chamber 1-5 is adapted to be placed in an open state to an external space and in a hermetic state by opening and closing the related gate valves 6a-6fprovided at opposite ends of the chamber. The gate valve 6a opens and closes between the atmosphere and the heating chamber 1, the gate valve 6b between the heating chamber 1 and the p-type layer deposition chamber 2, the gate valve 6c between the p-type layer deposition chamber 2 and the i-type layer deposition chamber 3, the gate valve 6d between the i-type layer deposition chamber 3 and the n-type layer deposition chamber 4, the gate valve 6ebetween the n-type layer deposition chamber 4 and the unload lock chamber 5, and the gate valve 6fbetween the unload lock chamber 5 and the atmosphere, respectively.

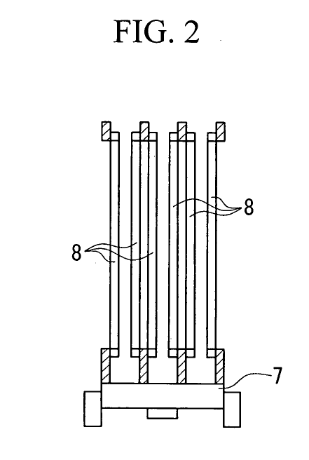

Each chamber 1-5 is internally adapted to receive the substrates 8, which are movable between each chamber 1-5 through opening and closing each gate valve 6b-6e. Each substrate 8, as shown in FIG. 2, is fixed vertically to a substrate holder 7, and each chamber 1-5 is internally provided with a not-shown conveying mechanism for moving the substrate holder 7 between each chamber 1-5.

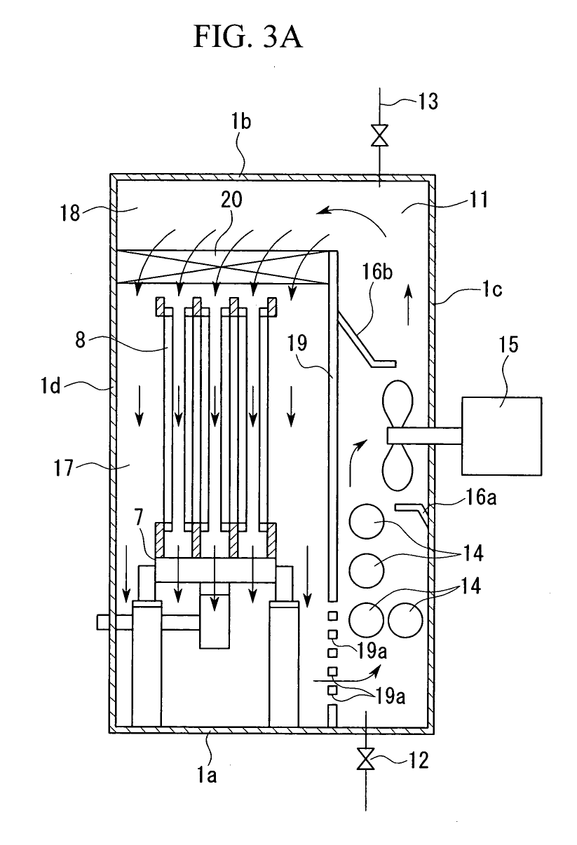

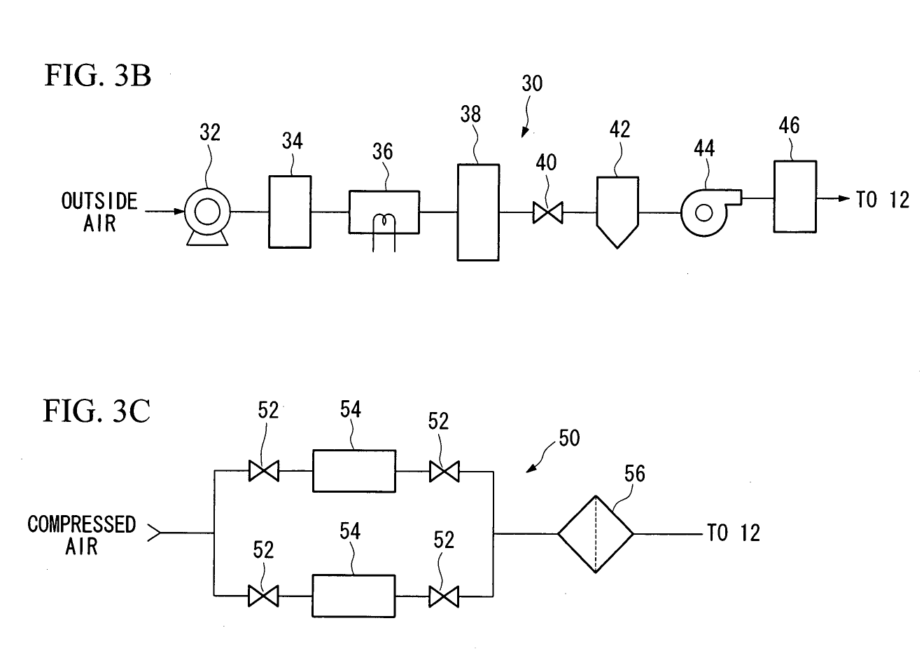

The heating chamber 1, as shown in FIG. 3A, is shaped like a box and surrounded by a plate-like bottom wall 1a, top wall 1b, and side walls 1c and 1d, and has the gate valves 6a and 6b extending in directions parallel to the surface of the FIG. 3A drawing. The heating chamber 1 heats the internally-disposed substrates 8 through heat exchange with a gas 11 (first gas such as, for example, nitrogen gas or inert gas) flowing inside the heating chamber 1, from which impurities such as moisture, organic substances and the like have been removed. The removal of the impurities such as moisture and organic substances may be performed, for example, by passing the gas through a compression cooler apparatus or filter apparatus.

More specifically, a compression cooler apparatus 30, as shown in FIG. 3B, may be constructed, for example, by a compressor 32, tank 34, condenser 36, receiver 38, selector valve 40, precooler 42, blower 44 and dehumidifier rotor 46, and the gas 11 free of impurities such as moisture and organic substances may be obtained by passing, for example, outside air through the above elements in the order mentioned. The gas 11 is thereafter supplied into the heating chamber 1 via a gas supply valve 12. Alternatively, a filter apparatus 50, as shown in FIG. 3C, may be constructed, for example, by two parallel-connected sets of selector valves 52, moisture/organic substance adsorber filters 54 and selector valves 52, and a downstream-located particle remover filter 56, and the gas 11 free of impurities such as moisture and organic substances may be obtained by passing, for example, compressed air through the filter apparatus 50. The gas 11 is thereafter supplied into the heating chamber 1 via the gas supply valve 12.

The bottom wall 1a is provided with a gas supply source including the gas supply valve 12 for supplying the gas 11 into the heating chamber 1, and the top wall 1b is provided with a gas exhaust opening 13 through which the gas inside the heating chamber 1 is evacuated to the outside. The side wall 1c is provided with a blower 15 for causing the gas 11, which has been heated at heat sources 14, to flow along an airway inside the heating chamber 1 and with a guide plate 16a located below the blower 15 for guiding the moving direction of the gas 11 which is blown by the blower 15.

The space inside the heating chamber 1 is composed of a space section 17 where the substrate holder 7 with substrates 8 fixed thereto is disposed and a space section 18 where the gas 11 is heated and blown, the space sections 17 and 18 being partitioned with a partition plate 19 and guide plate 20.

The partition plate 19 has a rectangular shape and is fixed vertically on the bottom wall 1a such that its surface lies parallel to the side wall 1c. The partition plate 19 is formed at a lower portion thereof with ventilating holes 19a for passage therethrough of the gas 11 and at an upper portion, above the blower 15, with a guide plate 16b which projects on the side of the space section 18 to guide the moving direction of the gas 11. A gap is formed between the upper end of the partition plate 19 and the top wall 1b so as to allow passage therethrough of the gas 11. The heat sources 14 are provided between the ventilating holes 19a and the blower 15 and heat the gas 11 inside the heating chamber 1 to approximately 250° C.

The guide plate 20 is disposed between the side face of the side wall 1d and the upper end of the partition plate 19 such that it guides the gas 11 from the space section 18 to the space section 17.

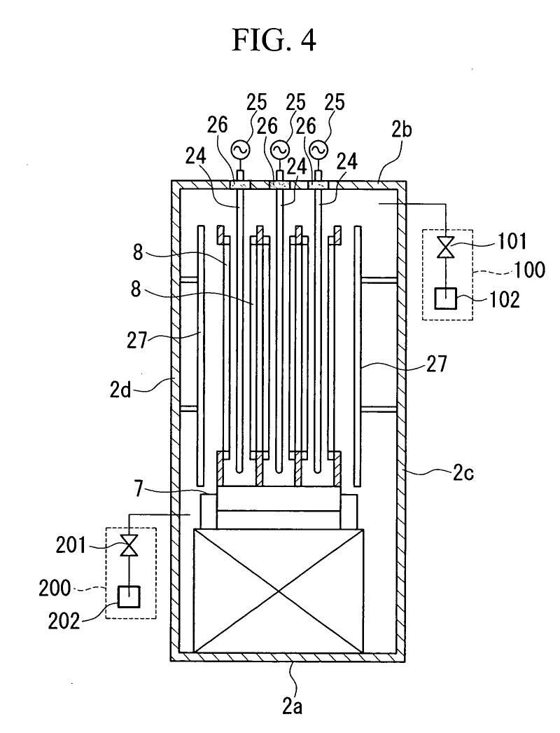

The p-type layer deposition chamber 2, as shown in FIG. 4, is shaped box-like in the same way as the heating chamber 1 and surrounded by a plate-like bottom wall 2a, top wall 2b, and side walls 2c, and has gate valves 6b and 6c extending in directions parallel to the surface of the FIG. 4 drawing. The p-type layer deposition chamber 2 deposits a p-type semiconductor thin film on surfaces of the substrates 8 disposed therein.

The side wall 2c is provided with a gas introduction apparatus 100 made up of a gas introduction valve 101 and a gas introduction source 102 for introducing a p-type layer depositing gas (second gas) into the p-type layer deposition chamber 2, and the side wall 2d is provided with a pumping system 200 made up of a pump valve 201 and a pump 202 for evacuating the gas from inside the p-type layer deposition chamber 2. Furthermore, each of the side walls 2c and 2d is provided with a heater 27 for heating and maintaining the heat of the substrates 8 with radiant heat.

The top wall 2b is mounted with high-frequency electrodes 24 for causing an electrical discharge of the gas supplied into the p-type layer deposition chamber 2, the high-frequency electrodes 24 connecting to respective high-frequency power sources 25. Each high-frequency electrode 24 is, for example, an inductively coupled type electrode made of a U-shaped rod-like metallic member and is disposed between substrates 8 and 8. The high frequency electrode 24 is insulated from the top wall 2b by means of an insulating block 26. The gas which is introduced into the p-type layer deposition chamber 2 may, for example, be a mixture gas of B₂H₆, SiH₄ and H₂, and the pressure inside the p-type layer deposition chamber 2 may be maintained, for example, at approximately 10-100 Pa.

The i-type layer deposition chamber 3 deposits an intrinsic semiconductor thin film on surfaces of the substrates 8 disposed therein and has the same construction as that of the p-type layer deposition chamber 2 except that the gas which is introduced into the i-type layer deposition chamber 3 is different. The gas which is introduced into the i-type layer deposition chamber 3 may, for example, be a mixture gas of SiH₄ and H₂, and the pressure inside the i-type layer deposition chamber 3 may be maintained, for example, at approximately 10-100 Pa as inside the p-type layer deposition chamber 2.

The n-type layer deposition chamber 4 deposits an n-type semiconductor thin film on surfaces of the substrates 8 disposed therein and has the same construction as that of the p-type layer deposition chamber 2 except for the gas to be introduced. The gas which is introduced into the n-type layer deposition chamber 4 may, for example, be a mixture gas of PH₃, SiH₄ and H₂, and the pressure inside the n-type layer deposition chamber 4 may likewise be maintained, for example, at approximately 10- 100 Pa.

The unload lock chamber 5 is for taking out the substrates 8 under atmospheric pressure.

A thin film depositing method which uses the thin film depositing apparatus of the above construction will now be described.

First, the substrate holder 7 with substrates 8 fixed thereto is disposed inside the heating chamber 1 through the gate valve 6a, which is maintained at a pressure slightly higher than the atmospheric pressure and filled with the gas 11, followed by closing the gate valve 6a. In this state, all the gate valves 6a-6eare closed, and the p-type layer deposition chamber 2, the i-type layer deposition chamber 3 and the n-type layer deposition chamber 4 are maintained in a predetermined vacuum state, for example, at approximately 1 Pa or less, preferably at less than 0.1 Pa.

Then, the gas 11 with impurities such as moisture and organic substances removed therefrom (for example, a nitrogen gas consisting almost only of nitrogen) is supplied into the heating chamber 1 through the gas supply valve 12. The pressure inside the heating chamber 1 is adjusted as required through the exhaust opening 13, while spreading the gas 11 all over the interior of the heating chamber 1. In this instance, heat is generated at the heat sources 14 to heat the gas 11 which is then passed in the direction of arrows in FIG. 3A and circulated inside the heating chamber 1 with the blower 15.

The gas 11, which has been heated at the heat sources 14 and blown with the blower 15 so as to reach the guide plate 20, is sent into the space section 17 where the substrates 8 are located. In the space section 17, the gas 11 contacts the substrates 8 to perform heat exchange therewith and heats the substrates 8. The time required for the heating is, for example, approximately 30 min.

The gas 11 used to heat the substrates 8 and lowered in temperature, moves from the space section 17 again into the space section 18 through the ventilating holes 1 9a and is reheated there by the heat sources 14 to a predetermined temperature. In this manner, the gas 11 is heated with the heat sources 14 and is blown by the blower 15 to move and circulate from the space section 18 to the space section 17, and from the space section 17 to the space section 18 inside the heating chamber 1, so as to heat the substrates 8. In this instance, because the gas 11 contains almost no impurities such as moisture and organic substances, almost no impurities are adsorbed on the surfaces of the substrates 8 which would impair properties of the thin films deposited thereon.

After heating substrates 8 to a predetermined temperature, the gate valve 6b is opened, and the substrate holder 7 and thus the substrates 8 are moved to the p-type layer deposition chamber 2 with a not-shown conveying means, followed by closing the gate valve 6b. In this state, the interior of the p-type layer deposition chamber 2 is evacuated to a pressure of, for example, 1 Pa or less, preferably of less than 0.1 Pa by means of a pumping system 200, while disposing, as required, a second substrate holder 7 with second substrates 8 fixed thereto inside the heating chamber 1 through the gate valve 6a, closing the gate valve 6a, and heating the second substrates 8. The time required for evacuating the p-type layer deposition chamber 2 to a predetermined pressure is, for example, approximately 3-5 min.

After evacuating the interior of the p-type layer deposition chamber 2 to a predetermined pressure, a mixture gas consisting, for example, of B₂H₆, SiH₄ and H₂ is introduced into the p-type layer deposition chamber 2 with the gas introduction apparatus 100, and the gas flow rate and pumping speed, the latter pumping being effected with the pumping system 200, are adjusted such that the interior pressure of the p-type layer deposition chamber 2 will be approximately 10-100 Pa. After completion of realizing the predetermined state, a high-frequency electric power is supplied from each high-frequency power source 25 to the relevant high-frequency electrode 24 to cause an electrical discharge and decomposition of the mixture gas. The components of the gas decomposed adhere to surfaces of the substrate 8 to deposit a p-type semiconductor thin film (p-type layer) thereon. The time required for depositing the p-type layer is approximately 2 min.

After depositing p-type layers on the surfaces of the substrates 8 in the p-type layer deposition chamber 2, the introduction of the gas is stopped, the interior of the p-type layer deposition chamber 2 is evacuated to a pressure of, for example, 1 Pa or less, preferably of less than 0.1 Pa, the substrate holder 7 and thus the substrates 8 are moved through the gate valve 6c into the i-type layer deposition chamber 3 with the not-shown conveying means, and the intrinsic semiconductor thin film (i-type layer) is deposited. The time required for depositing the i-type layer is approximately 20 min. In the meantime, if the second substrates 8 have been heated to a predetermined temperature, taking account of the time required for depositing the i-type layer on the substrates 8 and the time required for depositing the p-type layer on the second substrates 8, the second substrates 8 are moved as required into the p-type layer deposition chamber 2, and third substrates 8 are disposed as required in the heating chamber 1 to be heated. Thus, it may be arranged that on completion of processing precedent substrates 8 in each chamber 1-5, the next substrates 8 are sent as required in sequence into each chamber 1-5 so as to successively deposit thin layers on the substrates 8.

With the construction as mentioned above, because the gas 11 from which impurities such as moisture and organic substances have been removed is used as the gas which heats the substrates 8 through heat exchange, almost no impurities such as moisture and organic substances which would impair properties of the thin films deposited thereon are adsorbed on surfaces of the substrates 8 during heating of the substrates 8, and because the substrates 8, after being heated, are exposed to an atmosphere only of a gas which is the raw material of the films, it takes little time to evacuate the surroundings of the substrates 8 to remove the adsorbates adhering to the surfaces of the substrates 8. Thus, the time required for the evacuation prior to the film deposition can be shortened, with the result that the time required for depositing thin films can be shortened. Because it takes little time to remove adsorbates, it is not necessary to provide the load lock chamber with a radiation heating lamp for maintaining the heat of the substrates 8 during the evacuation of space around the substrates 8, thereby dispensing with the cost therefor. Furthermore, because almost no impurities such as moisture and organic substances which would degrade the properties of the thin films are adsorbed on the substrates 8, the properties of the thin films deposited on the substrates 8 will not be degraded.

Note that, although as the gas 11 from which impurities such as moisture and organic substances have been removed, a nitrogen gas from which impurities such as moisture and organic substances have been removed may be used, the gas 11 free of impurities such as moisture and organic substances is not limited to the nitrogen gas, and any inactive gas which will not give rise to adsorption on the substrates 8 and not effect the properties of the films during film deposition is usable.

Note that, although in the above embodiment the heating chamber 1 has not been configured to have its interior gas evacuated, the heating chamber 1 may be provided with a pumping system for evacuating the interior gas. In that case, after heating the substrates 8 in the heating chamber 1, the space around the substrates in the heating chamber 1 may be evacuated, and then the substrates 8 may be moved to the p-type layer deposition chamber 2 to have the p-type thin film deposited thereon.

Note that in the above embodiment, the p-type layer deposition chamber 2, the i-type layer deposition chamber 3, and the n-type layer deposition chamber 4 are provided downstream of the heating chamber 1. However, it is also possible to provide, instead of these three chambers, a single deposition chamber downstream of the heating chamber 1 which is capable of depositing the three layers of the p-type, i-type and n-type layers. Furthermore, the heating chamber 1 and the p-type layer deposition chamber 2, or the heating chamber 1 and a single layer deposition chamber capable of depositing all the three layers may be combined into a single chamber. In addition, the unload lock chamber 5 and the n-type layer deposition chamber 4 may be made the same. In this instance, the gate valve 6emay be provided at the atmosphere side with a nitrogen-purged atmospheric pressure space so as to prevent impurities from entering the n-type layer deposition chamber 4. Alternatively, an air curtain of nitrogen may be provided on the atmosphere side of the gate valve 6e.

Having now fully described the invention, it will be apparent to one of ordinary skill in the art that many changes and modifications can be made thereto without departing from the spirit and scope of the invention as set forth in the appended claims.

What is claimed is:

1. A thin film depositing method comprising the steps of:
placing a substrate in a chamber;
causing a gas to flow into said chamber to heat said substrate through heat exchange with said gas;
evacuating said chamber; and
depositing a film on a surface of said substrate heated in said chamber.

2. A thin film depositing method comprising the steps of:
placing a substrate in a heating chamber;
causing a first gas to flow into said heating chamber to heat said substrate through heat exchange with said first gas;
moving said substrate to a deposition chamber, evacuating said deposition chamber, and then supplying a second gas into said deposition chamber; and
causing an electrical discharge in said second gas such that said second gas decomposes into components which adhere to a surface of said substrate to deposit a film thereon,
wherein said first gas is a gas from which moisture and organic substances have been removed.

3. The thin film depositing method according to claim 2, wherein said first gas is an inert gas.

4. The thin film depositing method according to claim 2, wherein said first gas is nitrogen gas.

5. A thin film depositing apparatus comprising:
a chamber;
a substrate placed in said chamber;
a gas which flows inside said chamber to heat said substrate through heat exchange with said gas; and
a pumping system which evacuates said chamber;
whereby a film is deposited on a surface of said substrate in said chamber.

6. A thin film depositing apparatus comprising:
a heating chamber;
a substrate placed in said heating chamber;
a gas which flows inside said heating chamber to heat said substrate through heat exchange with said gas; and
a deposition chamber in which a film is deposited on a surface of said substrate, said deposition chamber being located downstream of and connected to said heating chamber through a valve,
wherein said gas is a gas from which moisture and organic substances have been removed.

7. The thin film depositing apparatus according to claim 6, wherein said gas is an inert gas.

8. The thin film depositing apparatus according to claim 6, wherein said gas is nitrogen gas.

9. The thin film depositing apparatus according to claim 6, further comprising a compression cooler which removes moisture and organic substances from said gas.

10. The thin film depositing apparatus according to claim 6, further comprising a filter device which removes moisture and organic substances from said gas.
